(19) United States
(12) Patent Application Publication
(10) Pub. No.: US 2026/0198114 A1
(43) Pub. Date: Jul. 9, 2026

(54) SEMICONDUCTOR APPARATUS AND ELECTRONIC DEVICE

(71) Applicant: SONY SEMICONDUCTOR SOLUTIONS CORPORATION, Kanagawa (JP)

(72) Inventors: Izumi KIMOTO, Kanagawa (JP); Keiji NISHIDA, Kanagawa (JP); Kohei DOI, Kanagawa (JP); Harumi TANAKA, Kanagawa (JP)

(73) Assignee: SONY SEMICONDUCTOR SOLUTIONS CORPORATION, Kanagawa (JP)

(21) Appl. No.: 19/127,640

(22) PCT Filed: Nov. 20, 2023
(86) PCT No.: PCT/JP2023/041584

§ 371 Date: May 6, 2025

(30) Foreign Application Priority Data
Nov. 28, 2022 (JP) 2022-189127

(51) Int. Cl. H10F 39/00; H04N 25/77; H10F 39/18

(52) U.S. Cl. CPC H10F 39/80373; H04N 25/77; H10F 39/014; H10F 39/182; H10F 39/809; H10F 39/811

(57) ABSTRACT

To facilitate connection between a gate electrode of a charge transfer section and wiring. The semiconductor apparatus includes a connection region, a photoelectric conversion section, a charge holding section, and a charge transfer section. The connection region is on the surface of the semiconductor substrate and to which wiring is connected. The photoelectric conversion section and the charge holding section are in the semiconductor substrate. The charge transfer section includes a MOS transistor including a gate electrode including a vertical electrode section disposed in the semiconductor substrate and a flat plate electrode section embedded in a surface of the semiconductor substrate and having a size in a plane direction of the semiconductor substrate different from that of the vertical electrode section and having wiring connected to an upper surface, and transfers a charge of the photoelectric conversion section to the charge holding section.

### FIELD

The present disclosure relates to a semiconductor apparatus and an electronic device.

### BACKGROUND

In a photodetection apparatus such as an imaging element, a photoelectric conversion section arranged in a pixel generates a charge in accordance with incident light during an exposure period, and a charge transfer section transfers the generated charge to a charge holding section after the exposure period has elapsed. Thereafter, an image signal is generated by a circuit arranged in the pixel on the basis of the charge held in the charge holding section. For such an imaging element, an imaging element in which a photoelectric conversion section is disposed on a back surface side of a semiconductor substrate is used. In this imaging element, a charge transfer section that transfers the charge generated by the photoelectric conversion section to a charge holding section arranged on the front surface side of the semiconductor substrate is used. For example, a charge transfer section including a transfer gate including a transfer gate electrode that is a planar electrode and a vertical gate electrode formed in a depth direction has been proposed (see, for example, Patent Literature 1).

### CITATION LIST

### Patent Literature

Patent Literature 1: JP 2018-190797 A

### SUMMARY

### Technical Problem

However, in the above-described conventional technique, a part of the gate electrode is formed in a shape protruding from the surface of the semiconductor substrate. For this reason, there is a problem that the heights of the upper surface of the charge holding section and the upper surface of the gate electrode are different, and the heights of the contact surfaces of the contact plugs connected to the upper surface of the charge holding section and the upper surface of the gate electrode are not aligned. As a result, there is a problem that it is difficult to connect the contact plug to the gate electrode and the charge holding section.

Therefore, the present disclosure proposes a semiconductor apparatus and an electronic device that facilitate connection between a gate electrode of a charge transfer section and wiring.

### Solution to Problem

A semiconductor apparatus according to the present disclosure includes a connection region, a photoelectric conversion section, a charge holding section, a charge transfer section and a signal generation section. The connection region is disposed on a surface of a semiconductor substrate and is a region to which wiring is connected. The photoelectric conversion section is disposed in the semiconductor substrate and is configured to perform photoelectric conversion of incident light. The charge holding section is disposed in the semiconductor substrate and holds a charge generated by the photoelectric conversion. The charge transfer section is configured by a MOS transistor including a gate electrode including a vertical electrode section disposed in the semiconductor substrate and a flat plate electrode section embedded in a surface of the semiconductor substrate, the flat plate electrode section having a size in a plane direction of the semiconductor substrate different from that of the vertical electrode section, the flat plate electrode section having wiring connected to an upper surface of the flat plate electrode section. The charge transfer section is configured to transfer a charge of the photoelectric conversion section to the charge holding section. The signal generation section generates a signal based on the charge held in the charge holding section.

### BRIEF DESCRIPTION OF DRAWINGS

FIG. 1 is a diagram illustrating an example of a schematic configuration of a photodetection apparatus according to a first embodiment of the present disclosure.

FIG. 2 is a diagram illustrating a configuration example of a pixel according to an embodiment of the present disclosure.

FIG. 3 is a diagram illustrating a configuration example of a pixel according to the first embodiment of the present disclosure.

FIG. 4 is a diagram illustrating a configuration example of a pixel according to the first embodiment of the present disclosure.

FIG. 5A is a diagram illustrating a configuration example of a gate electrode according to the first embodiment of the present disclosure.

FIG. 5B is a diagram illustrating a configuration example of a gate electrode according to the first embodiment of the present disclosure.

FIG. 6 is a diagram illustrating a configuration example of a gate electrode according to the first embodiment of the present disclosure.

FIG. 7A is a diagram illustrating an example of a method for manufacturing the gate electrode according to the first embodiment of the present disclosure.

FIG. 7B is a diagram illustrating an example of the method for manufacturing the gate electrode according to the first embodiment of the present disclosure.

FIG. 7C is a diagram illustrating an example of the method for manufacturing the gate electrode according to the first embodiment of the present disclosure.

FIG. 7D is a diagram illustrating an example of the method for manufacturing the gate electrode according to the first embodiment of the present disclosure.

FIG. 7E is a diagram illustrating an example of the method for manufacturing the gate electrode according to the first embodiment of the present disclosure.

FIG. 7F is a diagram illustrating an example of the method for manufacturing the gate electrode according to the first embodiment of the present disclosure.

FIG. 7G is a diagram illustrating an example of the method for manufacturing the gate electrode according to the first embodiment of the present disclosure.

FIG. 7H is a diagram illustrating an example of the method for manufacturing the gate electrode according to the first embodiment of the present disclosure.

FIG. 8 is a diagram illustrating an example of a schematic configuration of a photodetection apparatus according to a second embodiment of the present disclosure.

FIG. 9 is a diagram illustrating a configuration example of a pixel according to the second embodiment of the present disclosure.

FIG. 10 is a diagram illustrating a configuration example of a pixel according to the second embodiment of the present disclosure.

FIG. 11A is a diagram illustrating a configuration example of a pixel according to a third embodiment of the present disclosure.

FIG. 11B is a diagram illustrating a configuration example of a pixel according to the third embodiment of the present disclosure.

FIG. 12A is a diagram illustrating another configuration example of the pixel according to the third embodiment of the present disclosure.

FIG. 12B is a diagram illustrating another configuration example of the pixel according to the third embodiment of the present disclosure.

FIG. 13A is a diagram illustrating another configuration example of the pixel according to the third embodiment of the present disclosure.

FIG. 13B is a diagram illustrating another configuration example of the pixel according to the third embodiment of the present disclosure.

FIG. 14A is a diagram illustrating another configuration example of the pixel according to the third embodiment of the present disclosure.

FIG. 14B is a diagram illustrating another configuration example of the pixel according to the third embodiment of the present disclosure.

FIG. 15A is a diagram illustrating another configuration example of the pixel according to the third embodiment of the present disclosure.

FIG. 15B is a diagram illustrating another configuration example of the pixel according to the third embodiment of the present disclosure.

FIG. 16 is a diagram illustrating a configuration example of a pixel according to a fourth embodiment of the present disclosure.

FIG. 17 is a block diagram illustrating a configuration example of an imaging apparatus mounted on an electronic device.

FIG. 18 is a block diagram depicting an example of schematic configuration of a vehicle control system as an example of a mobile body control system to which the technology according to an embodiment of the present disclosure can be applied.

FIG. 19 is a diagram depicting an example of an installation position of an imaging section.

FIG. 20 is a view depicting an example of a schematic configuration of an endoscopic surgery system to which the technology according to an embodiment of the present disclosure can be applied.

FIG. 21 is a block diagram depicting an example of functional configurations of a camera head and a CCU depicted in FIG. 20.

### DESCRIPTION OF EMBODIMENTS

Hereinafter, embodiments of the present disclosure will be described in detail with reference to the drawings. The description will be given in the following order. Note that, in each of the following embodiments, the same parts are denoted by the same reference signs, and redundant description will be omitted.
1. First Embodiment
2. Second Embodiment
3. Third Embodiment
4. Fourth Embodiment
5. Configuration of Electronic Device
6. Application Example to Mobile Body
7. Application Example to Endoscopic Surgery System

### 1. First Embodiment

### [Configuration of Photodetection Apparatus]

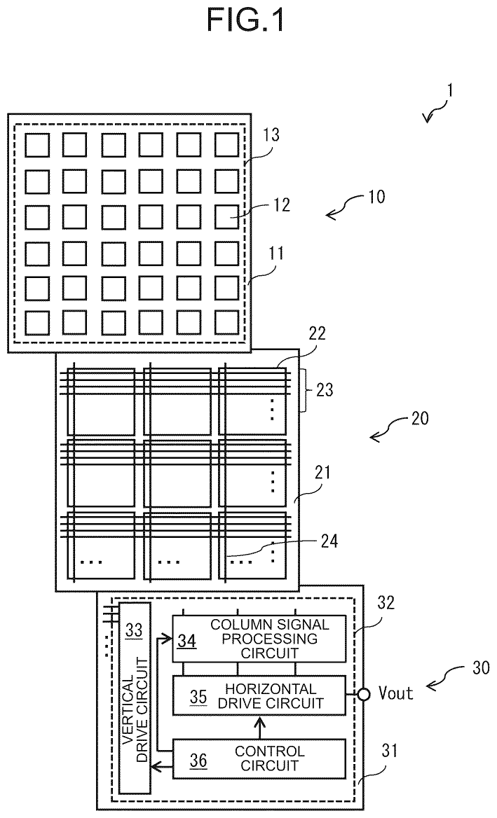

FIG. 1 is a diagram illustrating an example of a schematic configuration of a photodetection apparatus according to a first embodiment of the present disclosure. A photodetection apparatus 1 includes three substrates (first substrate 10, second substrate 20, and third substrate 30). The photodetection apparatus 1 has a three-dimensional structure formed by bonding three substrates (first substrate 10, second substrate 20, and third substrate 30). The first substrate 10, the second substrate 20, and the third substrate 30 are laminated in this order.

The first substrate 10 includes a plurality of pixels 12 that performs photoelectric conversion on a semiconductor substrate 11. The semiconductor substrate 11 corresponds to a specific example of a “semiconductor substrate” of the present disclosure. The plurality of pixels 12 is provided in a matrix in a pixel array section 13 of the first substrate 10. The second substrate 20 includes, on a semiconductor substrate 21, one readout circuit 22 for each of four pixels 12, which outputs a pixel signal based on a charge output from the pixel 12. The semiconductor substrate 21 corresponds to a specific example of a “second semiconductor substrate” of the present disclosure. Furthermore, the readout circuit 22 corresponds to a specific example of a “signal generation section” of the present disclosure. The second substrate 20 includes a plurality of pixel drive lines 23 extending in the row direction and a plurality of vertical signal lines 24 extending in the column direction. The third substrate 30 includes a logic circuit 32 that processes a pixel signal on a semiconductor substrate 31. The logic circuit 32 includes, for example, a vertical drive circuit 33, a column signal processing circuit 34, a horizontal drive circuit 35, and a control circuit 36. The logic circuit 32 (specifically, the horizontal drive circuit 35) outputs the output voltage Vout for each pixel 12 to the outside. In the logic circuit 32, for example, a low-resistance region constituted by silicide formed using a self aligned silicide (salicide) process such as CoSi₂ or NiSi may be formed on the surface of the impurity diffusion region in contact with the source electrode and the drain electrode.

For example, the vertical drive circuit 33 sequentially selects the plurality of pixels 12 row by row. The column signal processing circuit 34 performs, for example, correlated double sampling (CDS) processing on the pixel signal output from each pixel 12 of the row selected by the vertical drive circuit 33. The column signal processing circuit 34 extracts a signal level of a pixel signal by performing CDS processing, for example, and holds pixel data corresponding to the amount of received light of each pixel 12. For example, the horizontal drive circuit 35 sequentially outputs the pixel data held in the column signal processing circuit 34 to the outside. The control circuit 36 controls driving of each block (vertical drive circuit 33, column signal processing circuit 34, and horizontal drive circuit 35) in the logic circuit 32, for example.

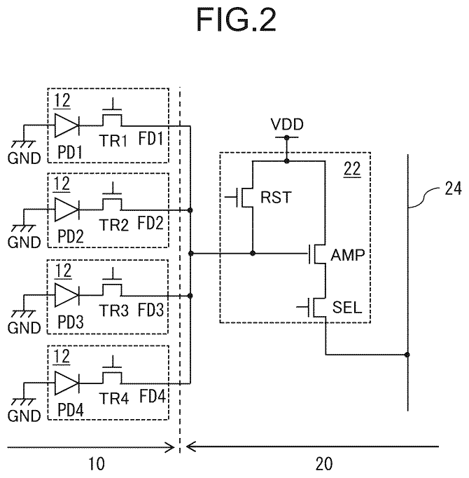

FIG. 2 is a diagram illustrating a configuration example of a pixel according to an embodiment of the present disclosure. FIG. 2 is a circuit diagram illustrating a configuration example of the pixel 12, and illustrates an example of the pixel 12 and the readout circuit 22. Hereinafter, as illustrated in FIG. 2, a case where four pixels 12 share one readout circuit 22 will be described. Here, “sharing” means that the outputs of the four pixels 12 are input to the common readout circuit 22. The column signal processing circuit 34 corresponds to a specific example of a “processing circuit” of the present disclosure.

Each pixel 12 has a common component. In FIG. 2, in order to distinguish the components of each pixel 12 from each other, an identification number (1, 2, 3, and 4) is added to the end of the reference sign of the component of each pixel 12. Hereinafter, in a case where it is necessary to distinguish the components of each pixel 12 from each other, an identification number is assigned to the end of the reference sign of the component of each pixel 12, but in a case where it is not necessary to distinguish the components of each pixel 12 from each other, the identification number at the end of the reference sign of the component of each pixel 12 is omitted. Note that the photodetection apparatus 1 is a specific example of a “semiconductor apparatus” of the present disclosure.

Each pixel 12 includes, for example, a photodiode PD, a charge transfer section TR electrically connected to the photodiode PD, and a floating diffusion FD constituting a charge holding section that temporarily holds a charge output from the photodiode PD via the charge transfer section TR. The photodiode PD corresponds to a specific example of a “photoelectric conversion element” of the present disclosure. The photodiode PD performs photoelectric conversion to generate a charge corresponding to the amount of received light. The cathode of the photodiode PD is electrically connected to the source of the charge transfer section TR, and the anode of the photodiode PD is electrically connected to a reference potential line (for example, ground). The drain of the charge transfer section TR is electrically connected to the floating diffusion FD, and the gate of the charge transfer section TR is electrically connected to the pixel drive line 23. The charge transfer section TR is, for example, a metal oxide semiconductor (MOS) transistor.

The floating diffusion FD of each pixel 12 sharing one readout circuit 22 is electrically connected to each other and is electrically connected to an input terminal of the common readout circuit 22. The readout circuit 22 includes, for example, a reset transistor RST, a selection transistor SEL, and an amplification transistor AMP. Note that the selection transistor SEL may be omitted as necessary. The source of the reset transistor RST (the input terminal of the readout circuit 22) is electrically connected to the floating diffusion FD, and the drain of the reset transistor RST is electrically connected to the power supply line VDD and the drain of the amplification transistor AMP. The gate of the reset transistor RST is electrically connected to the pixel drive line 23 (see FIG. 1). The source of the amplification transistor AMP is electrically connected to the drain of the selection transistor SEL, and the gate of the amplification transistor AMP is electrically connected to the source of the reset transistor RST. The source of the selection transistor SEL (the output terminal of the readout circuit 22) is electrically connected to the vertical signal line 24, and the gate of the selection transistor SEL is electrically connected to the pixel drive line 23 (see FIG. 1).

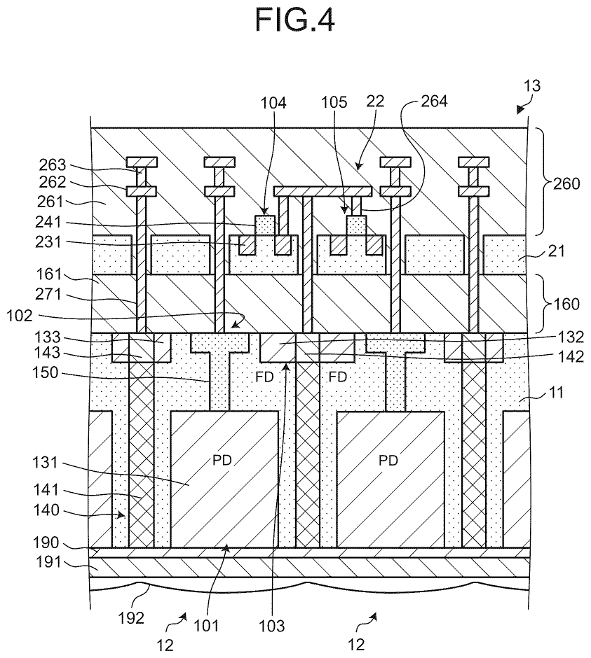

When turned on, the charge transfer section TR transfers the charge of the photodiode PD to the floating diffusion FD. The gate (transfer gate TG) of the charge transfer section TR extends from the surface of the semiconductor substrate 11 to a depth reaching the PD 101 through the well region, for example, as illustrated in FIG. 4 to be described later. The reset transistor RST resets the potential of the floating diffusion FD to a predetermined potential. When the reset transistor RST is turned on, the potential of the floating diffusion FD is reset to the potential of the power supply line VDD. The selection transistor SEL controls the output timing of the pixel signal from the readout circuit 22. The amplification transistor AMP generates a signal of a voltage corresponding to the level of the charge held in the floating diffusion FD as a pixel signal. The amplification transistor AMP constitutes a source follower type amplifier, and outputs a pixel signal having a voltage corresponding to the level of the charge generated in the photodiode PD. When the selection transistor SEL is turned on, the amplification transistor AMP amplifies the potential of the floating diffusion FD, and outputs a voltage corresponding to the potential to the column signal processing circuit 34 via the vertical signal line 24. The reset transistor RST, the amplification transistor AMP, and the selection transistor SEL are, for example, MOS transistors.

### [Configuration of Pixel]

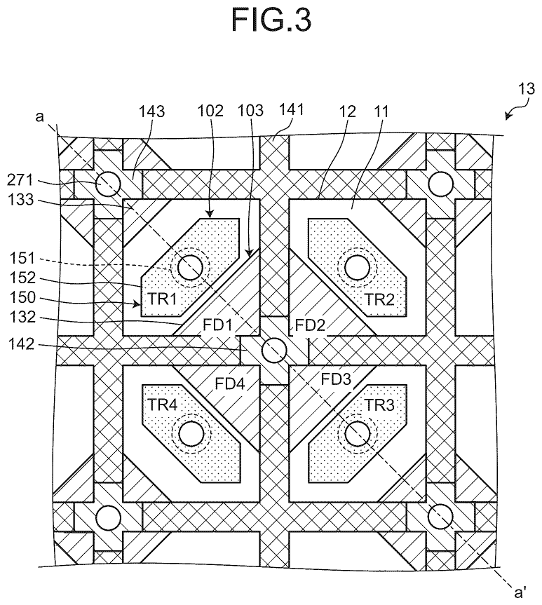

FIG. 3 is a diagram illustrating a configuration example of a pixel according to the first embodiment of the present disclosure. FIG. 3 is a plan view illustrating a configuration example of the pixel 12. Furthermore, FIG. 3 is a diagram illustrating a configuration of the pixel 12 on the front surface side of the semiconductor substrate 11. The four pixels 12 described in FIG. 2 are described on the semiconductor substrate of FIG. 3. A photoelectric conversion section 101 (not illustrated), a charge transfer section 102 (corresponding to TR in FIG. 2), and a charge holding section 103 (corresponding to FD in FIG. 2) are arranged for each of these pixels 12. A separation section 141 is arranged at the boundary of the pixel 12. Furthermore, a white circle in FIG. 3 represents through wiring 271 that connects the electrode or the like of the pixel 12 and the wiring in the wiring region of the second semiconductor substrate.

The charge holding section 103 in FIG. 3 includes a semiconductor region 132 corresponding to a floating diffusion. The four charge holding sections 103 are commonly connected to the embedded electrode 142 which is an electrode embedded in the semiconductor substrate 11. The embedded electrode 142 of FIG. 3 is disposed at a boundary of the pixel 12. The through wiring 271 is connected to the embedded electrode 142.

In addition, as described later, the photoelectric conversion section 101 is formed on the back surface side of the semiconductor substrate 11. The charge transfer section 102 includes a MOS transistor having a vertical transfer gate that transfers a charge in the thickness direction of the semiconductor substrate 11. FIG. 3 illustrates the gate electrode 150. The gate electrode 150 includes a vertical electrode section 151 and a flat plate electrode section 152. The flat plate electrode section 152 is configured to be embedded in the front surface side of the semiconductor substrate 11. The through wiring 271 is connected to the flat plate electrode section 152. The vertical electrode section 151 is disposed below the flat plate electrode section 152. As described later, the vertical electrode section 151 is an electrode whose bottom portion is in contact with the photoelectric conversion section 101 and is configured in a columnar shape. Note that the through wiring 271 connected to the flat plate electrode section 152 corresponds to a specific example of the “first columnar wiring” of the present disclosure.

A semiconductor region 133 is arranged at a corner portion of the pixel 12 facing the charge holding section 103. The semiconductor region 133 is a semiconductor region configured to have a relatively high impurity concentration, and transmits a reference potential to the well region of the semiconductor substrate 11. The embedded electrode 143 is connected to the semiconductor region 133, and the through wiring 271 is connected to the embedded electrode 143. The reference potential is transmitted from the semiconductor substrate 21 of FIG. 1 to the well region of the semiconductor substrate 11 via the through wiring 271, the embedded electrode 143, and the semiconductor region 133. Note that the embedded electrodes 142 and 143 correspond to a specific example of the “connection region” of the present disclosure. Note that the through wiring 271 connected to the embedded electrodes 142 and 143 corresponds to a specific example of the “second columnar wiring” of the present disclosure.

FIG. 4 is a diagram illustrating a configuration example of a pixel according to the first embodiment of the present disclosure. FIG. 4 is a cross-sectional view illustrating a configuration example of the pixel 12. The pixel 12 in FIG. 4 includes a semiconductor substrate 11, a wiring region 160, a semiconductor substrate 21, a wiring region 260, a color filter 191, and an on-chip lens 192. Note that FIG. 4 is a diagram schematically illustrating a shape of a cross section taken along line a-a′ in FIG. 3.

The semiconductor substrate 11 is a semiconductor substrate on which the photoelectric conversion section 101 and the like are disposed. The semiconductor substrate 11 can be constituted by, for example, silicon (Si). The photoelectric conversion section 101 (corresponding to the PD in FIG. 2) is disposed in a well region formed in the semiconductor substrate 11. For convenience, the semiconductor substrate 11 in FIG. 4 is assumed to constitute a p-type well region. By arranging n-type and p-type semiconductor regions in the p-type well region, an element (diffusion layer thereof) can be formed. A rectangle described in the semiconductor substrate 11 of FIG. 4 represents a semiconductor region.

The separation section 141 is arranged on the semiconductor substrate 11 at the boundary of the pixel 12. The separation section 141 electrically and optically separates the pixels 12 from each other. The separation section 141 is disposed in a groove-shaped opening 140 penetrating the semiconductor substrate 11. The separation section 141 can be constituted by, for example, silicon oxide (SiO₂).

The embedded electrodes 142 and 143 are disposed in the separation section 141. The embedded electrodes 142 and 143 can be constituted by, for example, polycrystalline silicon containing impurities.

The photoelectric conversion section 101 includes an n-type semiconductor region 131. Specifically, a photodiode constituted by a pn junction formed at the interface between the n-type semiconductor region 131 and the surrounding p-type semiconductor region or well region corresponds to the photoelectric conversion section 101. As illustrated in FIG. 4, the photoelectric conversion section 101 is disposed in the vicinity of the back surface of the semiconductor substrate 11.

The charge holding section 103 includes an n-type semiconductor region 132 configured to have a relatively high impurity concentration. The n-type semiconductor region 132 corresponds to a floating diffusion. The charge holding section 103 in FIG. 4 is arranged in the vicinity of the front surface of the semiconductor substrate 11. The semiconductor region 132 is connected to the embedded electrode 142.

The charge transfer section 102 includes the gate electrode 150 described above. When an ON voltage is applied to the gate electrode 150, a channel is formed in a well region adjacent to the gate electrode 150, and the photoelectric conversion section 101 and the charge holding section 103 are electrically connected to each other. As a result, the charge accumulated in the photoelectric conversion section 101 is transferred to the charge holding section 103. The gate electrode 150 can be constituted by polycrystalline silicon containing impurities. Note that a gate insulating film (not illustrated) is disposed between the gate electrode 150 and the semiconductor substrate 11.

The semiconductor region 133 is arranged in the well region of the semiconductor substrate 11. The semiconductor region 133 is a semiconductor region configured to have a relatively high impurity concentration. The embedded electrode 143 is connected to the semiconductor region 133. By disposing the semiconductor region 133, resistance between the well region and the embedded electrode 142 can be reduced.

An insulating film 190 is disposed on the back surface of the semiconductor substrate 11. The insulating film 190 can be constituted by, for example, silicon oxide (SiO₂) or silicon nitride (SiN).

The wiring region 160 is a region in which wiring that is disposed on the front surface of the semiconductor substrate 11 and transmits a signal or the like of an element is disposed. The wiring region 160 of FIG. 4 includes an insulating layer 161. The insulating layer 161 insulates the gate electrode 150, wiring, and the like disposed on the surface of the semiconductor substrate 11. The insulating layer 161 can be constituted by, for example, SiO₂.

The semiconductor substrate 21 is a semiconductor substrate on which the readout circuit 22 is disposed. The semiconductor substrate 21 is laminated on the semiconductor substrate 11. The back surface of the semiconductor substrate 21 is bonded to the surface of the wiring region 160 of the semiconductor substrate 11, and the semiconductor substrates 11 and 21 are laminated. Similarly to the semiconductor substrate 11, the semiconductor substrate 21 can be constituted by Si.

As described above, the readout circuit 22 is disposed on the semiconductor substrate 21. A reset transistor 104 (corresponding to RST in FIG. 2) and an amplification transistor 105 (corresponding to AMP in FIG. 2) of the readout circuit 22 are illustrated on the semiconductor substrate 21 in FIG. 4. The semiconductor element of the readout circuit 22 includes a semiconductor region 231 and a gate electrode 241 formed on a semiconductor substrate 21.

The wiring region 260 is a wiring region disposed on the front surface of the semiconductor substrate 21. The wiring region 260 includes wiring 262, a via plug 263, a contact plug 264, and an insulating layer 261.

Similarly to the insulating layer 161, the insulating layer 261 insulates wiring and the like. The insulating layer 261 can be constituted by, for example, SiO₂. The wiring 262 transmits a signal or the like to the element of a pixel block 100. The wiring 262 can be constituted by metal such as copper (Cu) or W, for example. The via plug 263 connects the wiring 262 formed in different layers. The via plug 263 can be constituted by, for example, columnar Cu or the like. In addition, the contact plug 264 electrically connects the wiring 262 and a member or the like of the semiconductor substrate 21. The contact plug 264 can be constituted by, for example, a columnar W or the like.

In addition, the through wiring 271 is disposed between the gate electrode 150 and the embedded electrodes 142 and 143 of the semiconductor substrate 11 and the wiring 262 of the wiring region 260. The through wiring 271 can be constituted by, for example, columnar Cu or the like.

The color filter 191 is an optical filter that transmits light of a predetermined wavelength among the incident light. As the color filter 191, for example, a color filter that transmits red light, green light, and blue light can be used.

The on-chip lens 192 is a lens that condenses incident light. The on-chip lens 192 is formed in, for example, a hemispherical shape, and condenses incident light on the photoelectric conversion section 101 or the like.

### [Configuration of Gate Electrode]

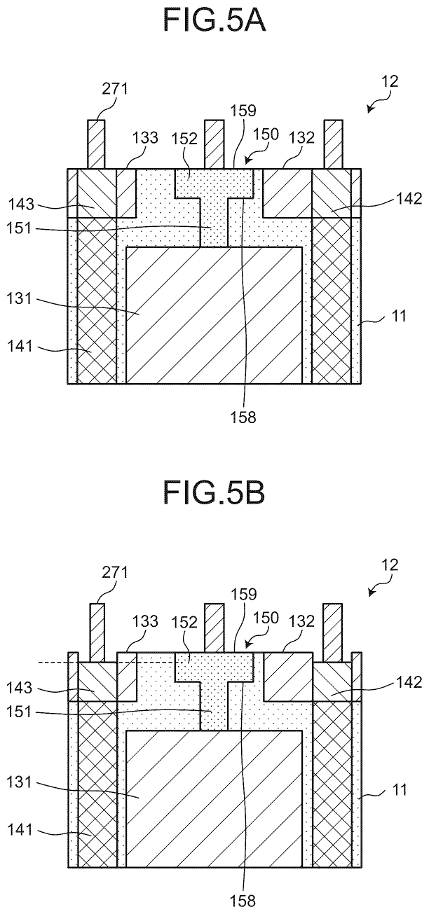

FIGS. 5A and 5B are diagrams illustrating a configuration example of a gate electrode according to the first embodiment of the present disclosure. FIGS. 5A and 5B are cross-sectional views illustrating a configuration example of the pixel 12 similarly to FIG. 4. For convenience, reference signs and the like are omitted in FIGS. 5A and 5B.

As illustrated in FIG. 5A, the gate electrode 150 includes the vertical electrode section 151 and the flat plate electrode section 152. The vertical electrode section 151 is an electrode that has a columnar shape with a bottom portion in contact with the photoelectric conversion section 101 and transfers the charge of the photoelectric conversion section 101 in the thickness direction of the semiconductor substrate 11. The flat plate electrode section 152 is configured to be embedded in the front surface side of the semiconductor substrate 11. The flat plate electrode section 152 is an electrode that transfers charges in a direction along the surface of the semiconductor substrate 11. In addition, the flat plate electrode section 152 is configured such that the size in the plane direction of the semiconductor substrate 11 is different from that of the vertical electrode section 151. FIG. 5A illustrates an example in which the flat plate electrode section 152 is configured to have a size larger than that of the vertical electrode section 151 in the plane direction of the semiconductor substrate 11. Further, the flat plate electrode section 152 is formed in a shape whose surface is exposed to the wiring region 160, and the through wiring 271 is connected thereto. Since the flat plate electrode section 152 is configured to have a size larger than that of the vertical electrode section 151, the flat plate electrode section 152 and the through wiring 271 can be connected even in a case where the position of the through wiring 271 is shifted.

The flat plate electrode section 152 of FIG. 5A illustrates an example in which the upper surface 159 is configured to have substantially the same height as the front surface of the semiconductor substrate 11. Specifically, the flat plate electrode section 152 is configured such that a difference in height of the upper surface 159 from the front surface of the semiconductor substrate 110 is 100 nm or less. As a result, the position of the bottom portion of the through wiring 271 can be aligned in the vicinity of the front surface of the semiconductor substrate 11, and the through wiring 271 and the flat plate electrode section 152 can be easily connected. In addition, FIG. 5A illustrates an example in which the upper surfaces of the embedded electrodes 142 and 143 and the upper surface 159 of the flat plate electrode section 152 are configured to have substantially the same height. Specifically, the flat plate electrode section 152 has a height difference of 100 nm or less between the upper surface 159 thereof and the upper surfaces of the embedded electrodes 142 and 143. By adopting this configuration, in the embedded electrodes 142 and 143 and the flat plate electrode section 152, the positions (heights) connected to the respective through wiring 271 can be aligned, and the embedded electrodes 142 and 143 and the flat plate electrode section 152 can be easily connected to the respective through wiring 271.

As described above, by embedding at least a part of the flat plate electrode section 152 in the front surface of the semiconductor substrate 11, the height of the flat plate electrode section 152 with respect to the front surface of the semiconductor substrate 11 can be adjusted. As a result, the height of the upper surface 159 of the flat plate electrode section 152 of the gate electrode 150 and the height of the upper surfaces of the embedded electrodes 142 and 143 can be aligned. Therefore, contact surfaces of the contact plugs connected to the flat plate electrode section 152 and the contact plugs connected to the embedded electrodes 142 and 143 can be aligned in height.

FIG. 5B illustrates an example in which the height of the upper surfaces of the embedded electrodes 142 and 143 is configured to be the height between the upper surface 159 and the lower surface 158 of the flat plate electrode section 152. In this case, even in a case where the height of the upper surfaces of the embedded electrodes 142 and 143 changes due to variations in the manufacturing process, it is possible to facilitate connection with the flat plate electrode section 152 and the through wiring 271.

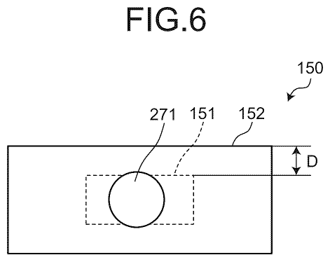

FIG. 6 is a diagram illustrating a configuration example of a gate electrode according to the first embodiment of the present disclosure. FIG. 6 is a plan view of the gate electrode 150 as viewed from the wiring region 160 side. Note that an example in which the vertical electrode section 151 and the flat plate electrode section 152 in FIG. 6 are configured in a rectangular shape in plan view is illustrated. As described above, the flat plate electrode section 152 can be configured to have a larger size in the plane direction of the semiconductor substrate 11 than the vertical electrode section 151. Here, the distance D between the end portion of the flat plate electrode section 152 and the end portion of the vertical electrode section 151 can be adjusted according to the shape of the through wiring 271. This makes it possible to connect the flat plate electrode section 152 and the through wiring 271 in a case where the position of the through wiring 271 is displaced. For example, the distance D can be larger than a length of 30% of the diameter of the through wiring 271. That is, the flat plate electrode section 152 can be configured to have a shape of an end portion extended outward by 30% or more of the diameter of the through wiring 271 with respect to the end portion of the vertical electrode section 151. As described above, the flat plate electrode section 152 can be configured to have a size corresponding to the through wiring 271.

### [Method for Manufacturing Gate Electrode]

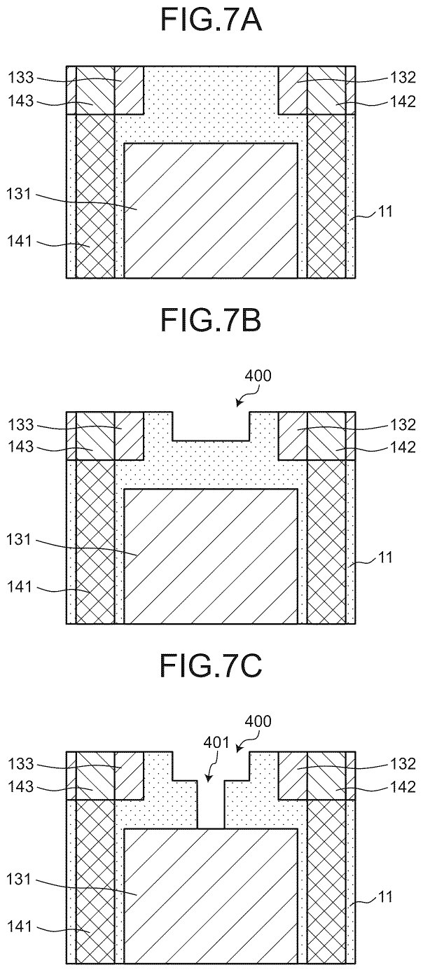

FIG. 7A-7H is a diagram illustrating an example of the method for manufacturing the gate electrode according to the first embodiment of the present disclosure. FIG. 7A-7H is a diagram illustrating an example of a manufacturing process of the gate electrode 150. First, the separation section 141 and the semiconductor regions 132 and 133 are formed on the semiconductor substrate 11. Next, the embedded electrodes 142 and 143 are formed in the separation section 141 (FIG. 7A).

Next, an opening 400 is formed on the front surface side of the semiconductor substrate 11 (FIG. 7B). Next, an opening 401 is formed in the opening 400 of the semiconductor substrate 11 (FIG. 7C). The openings 400 and 401 can be formed by, for example, dry etching.

Next, a sacrificial oxide film 402 is formed in the openings 400 and 401 (FIG. 7D). Next, ion implantation is performed on the opening 401 to form a semiconductor region 139 (not illustrated in FIG. 4) in a region adjacent to the opening 401 (FIG. 7E). Next, the sacrificial oxide film 402 is removed (FIG. 7F).

Next, a material film 403 of the gate electrode 150 is disposed on the front surface side of the semiconductor substrate 11 including the openings 400 and 401 (FIG. 7G). As the material film 403, a polycrystalline silicon film containing impurities can be used. Furthermore, the material film 403 can be formed by, for example, chemical vapor deposition (CVD). Next, the material film 403 in a region other than the openings 400 and 401 is removed (FIG. 7H). This can be performed by etching (etching back) the material film 403. Through the above steps, the gate electrode 150 can be manufactured.

As described above, in the photodetection apparatus 1 according to the first embodiment of the present disclosure, the vertical electrode section 151 and the flat plate electrode section 152 are arranged on the gate electrode 150, and the upper surfaces of the flat plate electrode section 152, the embedded electrode 142, and the like are configured to have substantially the same height. Thus, the through wiring 271 can be easily connected to the gate electrode 150. Connection reliability can be improved.

### 2. Second Embodiment

The photodetection apparatus 1 of the first embodiment described above is configured by laminating a plurality of semiconductor substrates. On the other hand, a photodetection apparatus 1 according to a second embodiment of the present disclosure is different from the photodetection apparatus 1 according to the first embodiment described above in that the photodetection apparatus 1 includes one semiconductor substrate.

### [Configuration of Photodetection Apparatus]

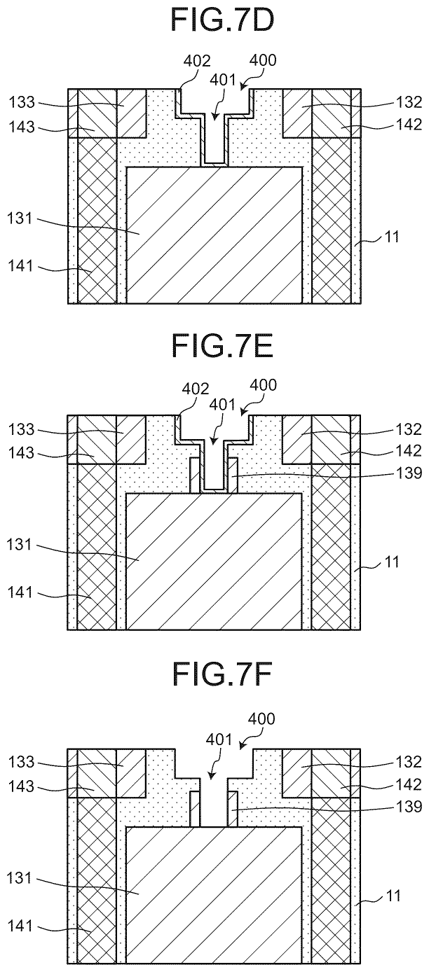

FIG. 8 is a diagram illustrating an example of a schematic configuration of a photodetection apparatus according to the second embodiment of the present disclosure. As illustrated in FIG. 8, the photodetection apparatus 1 of the present example includes a pixel array section (so-called imaging region) 13 in which pixels 12 including a plurality of photoelectric conversion elements are regularly and two-dimensionally arranged on a semiconductor substrate 11, for example, a silicon substrate, and a peripheral circuit section. The pixel 12 includes, for example, a photodiode serving as a photoelectric conversion element and a plurality of pixel transistors (so-called MOS transistors). The plurality of pixel transistors can include, for example, three transistors of a transfer transistor, a reset transistor, and an amplification transistor. In addition, a selection transistor may be added to form four transistors. The pixels 12 may have a shared pixel structure. This pixel sharing structure includes a plurality of photodiodes, a plurality of transfer transistors, one shared floating diffusion region, and one shared pixel transistor.

The peripheral circuit section includes a vertical drive circuit 33, a column signal processing circuit 34, a horizontal drive circuit 35, an output circuit 37, a control circuit 36, and the like.

The control circuit 36 receives an input clock and data instructing an operation mode and the like, and outputs data such as internal information of the imaging element. That is, the control circuit 36 generates a clock signal or a control signal serving as a reference of operations of the vertical drive circuit 33, the column signal processing circuit 34, the horizontal drive circuit 35, and the like on the basis of the vertical synchronization signal, the horizontal synchronization signal, and the master clock. Then, these signals are input to the vertical drive circuit 33, the column signal processing circuit 34, the horizontal drive circuit 35, and the like.

The vertical drive circuit 33 includes, for example, a shift register, selects the pixel drive line 23, supplies a pulse for driving pixels to the selected pixel drive line, and drives the pixels in units of rows. That is, the vertical drive circuit 33 sequentially selects and scans each pixel 12 in the pixel region 3 in the vertical direction in units of rows, and supplies a pixel signal based on a signal charge generated according to the amount of received light in, for example, a photodiode serving as a photoelectric conversion element of each pixel 12 to the column signal processing circuit 34 through the vertical signal line 9.

The column signal processing circuit 34 is arranged, for example, for each column of the pixels 12, and performs signal processing such as noise removal on the signals output from the pixels 12 of one row for each pixel column. That is, the column signal processing circuit 34 performs signal processing such as correlated double sampling (CDS) for removing fixed pattern noise unique to the pixel 12, signal amplification, and AD conversion. A horizontal selection switch (not illustrated) is connected and provided between an output stage of the column signal processing circuit 34 and a horizontal signal line 38. Note that the column signal processing circuit 34 is an example of a processing circuit described in the claims.

The horizontal drive circuit 35 includes, for example, a shift register, sequentially selects each of the column signal processing circuits 34 by sequentially outputting horizontal scanning pulses, and causes each of the column signal processing circuits 34 to output a pixel signal to the horizontal signal line 38.

The output circuit 37 performs signal processing on the signals sequentially supplied from each of the column signal processing circuits 34 through the horizontal signal line 38, and outputs the processed signals. For example, only buffering may be performed, or black level adjustment, column variation correction, various digital signal processing, and the like may be performed. The input/output terminal 39 exchanges signals with the outside.

### [Configuration of Pixel]

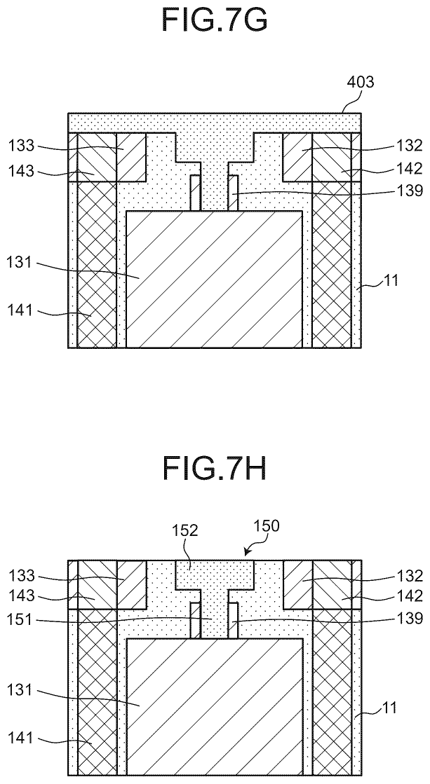

FIG. 9 is a diagram illustrating a configuration example of a pixel according to the second embodiment of the present disclosure. FIG. 9 is a plan view illustrating a configuration example of the pixel 12 similarly to FIG. 3. Similarly to FIG. 3, four pixels 12 are arranged. A common charge holding section 103 is arranged at the center of these pixels 12. The charge holding section 103 includes a semiconductor region 132. Furthermore, the reset transistor 104, the amplification transistor 105, and the selection transistor 106 are arranged on the semiconductor substrate 11 outside the four pixels 12. FIG. 9 illustrates an example in which the flat plate electrode section 152 has a rectangular shape in plan view. Note that a contact plug 163 is connected to the semiconductor region 132 of the charge holding section 103 and the flat plate electrode section 152. Note that the semiconductor region 132 corresponds to a specific example of a “connection region” of the present disclosure. The contact plug 163 connected to the semiconductor region 132 corresponds to a specific example of the “second columnar wiring” of the present disclosure. The contact plug 163 connected to the flat plate electrode section 152 corresponds to a specific example of the “first columnar wiring” of the present disclosure.

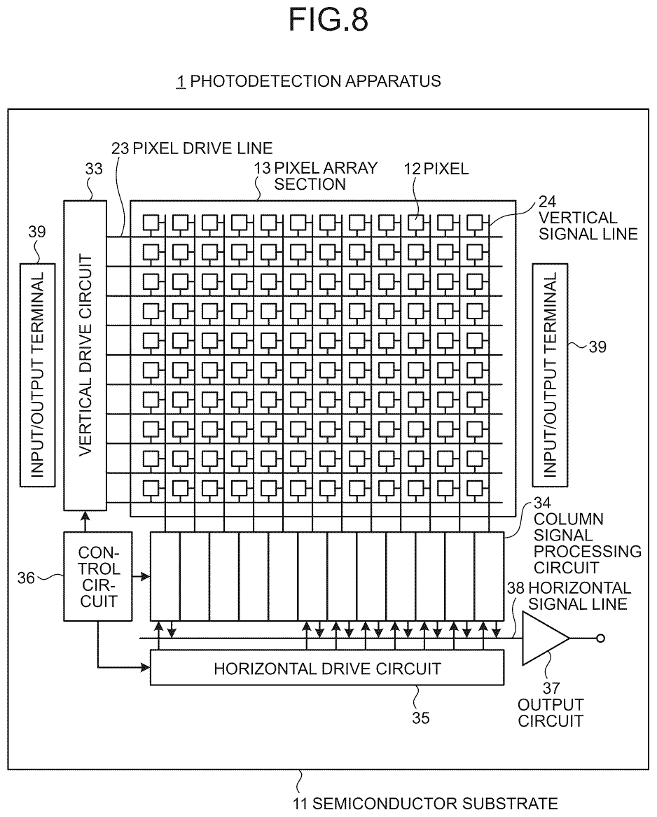

FIG. 10 is a diagram illustrating a configuration example of a pixel according to the second embodiment of the present disclosure. FIG. 10 is a cross-sectional view illustrating a configuration example of the pixel 12, similarly to FIG. 4. The pixel 12 in FIG. 10 is different from the pixel 12 in FIG. 4 in that the semiconductor substrate 21 is omitted.

The separation section 145 is arranged on the back surface side of the semiconductor substrate 11 at the boundary of the pixel 12. This separation section can be constituted by, for example, SiO₂. The separation section 145 is formed in a groove-shaped opening 144 formed on the back surface side of the semiconductor substrate 11. The separation section 138 is arranged on the front surface side of the semiconductor substrate 11 at the boundary of the pixel 12. The separation section 138 separates the element of the pixel 12 and the element of the readout circuit 22. The semiconductor region 132 constituting the charge holding section 103 is formed on the front surface side of the semiconductor substrate 11. Similarly to FIG. 4, the gate electrode 150 of the charge transfer section 102 includes the vertical electrode section 151 and the flat plate electrode section 152. In the wiring region 160, the insulating layer 161, the wiring 162, and the contact plug 163 are disposed. The contact plug 163 connects an element or the like of the semiconductor substrate 11 and the wiring 162. The contact plug 163 can be constituted by, for example, columnar tungsten (W).

Since the configuration of the photodetection apparatus 1 other than this is similar to the configuration of the photodetection apparatus 1 in the first embodiment of the present disclosure, the description thereof will be omitted.

As described above, the photodetection apparatus 1 according to the second embodiment of the present disclosure can easily connect the contact plug 163 to the gate electrode 150 in the pixel 12 including the semiconductor substrate 11.

### 3. Third Embodiment

Variations of the gate electrode 150 will be described.

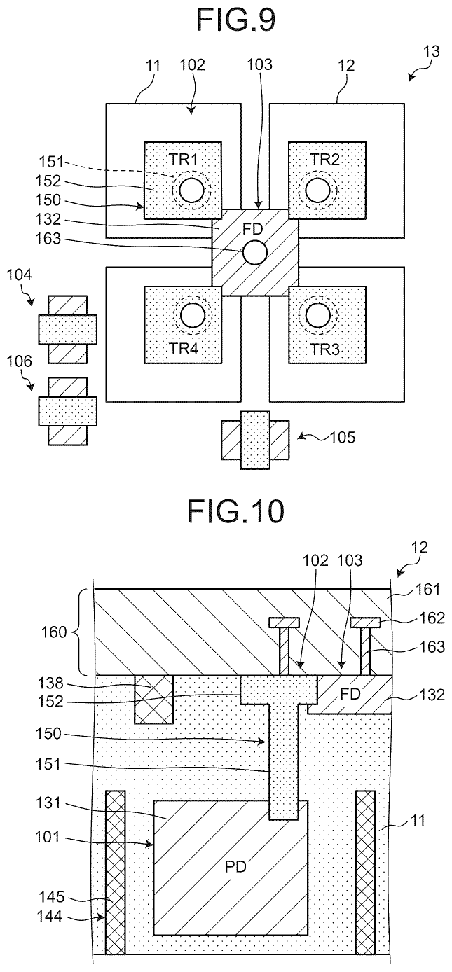

FIGS. 11A and 11B are diagrams illustrating a configuration example of a pixel according to a third embodiment of the present disclosure. FIG. 11A illustrates a configuration of a plane of the pixel 12, and FIG. 11B illustrates a configuration of a cross section of the pixel 12. An example in which the vertical electrode section 151 in FIG. 10 is formed in an elliptical shape in plan view is illustrated.

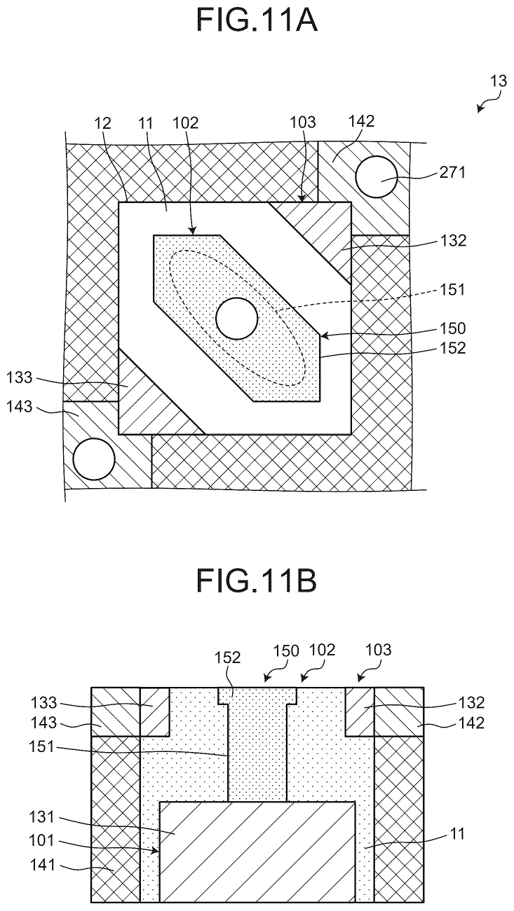

FIGS. 12A and 12B are diagrams illustrating another configuration example of the pixel according to the third embodiment of the present disclosure. FIG. 12A illustrates a configuration of a plane of the pixel 12, and FIG. 12B illustrates a configuration of a cross section of the pixel 12. FIGS. 12A and 12B illustrate examples of the charge transfer section 102 including a plurality of gate electrodes. The charge transfer section 102 in FIGS. 12A and 12B includes gate electrodes 150a and 150b.

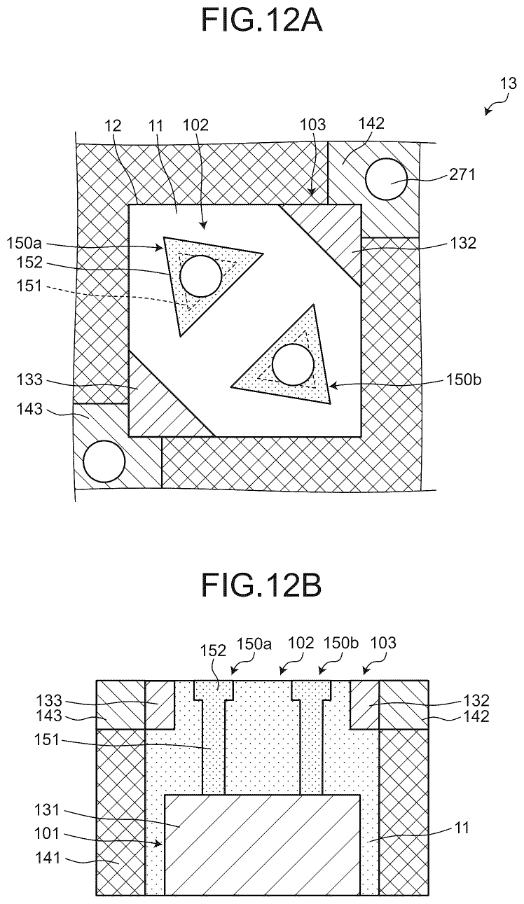

FIGS. 13A and 13B are diagrams illustrating another configuration example of the pixel according to the third embodiment of the present disclosure. FIG. 13A illustrates a configuration of a plane of the pixel 12, and FIG. 13B illustrates a configuration of a cross section of the pixel 12. FIGS. 13A and 13B illustrate examples of the gate electrode 150 including the plurality of vertical electrode sections 151. The gate electrode 150 in FIGS. 13A and 13B includes vertical electrode sections 151a and 151b.

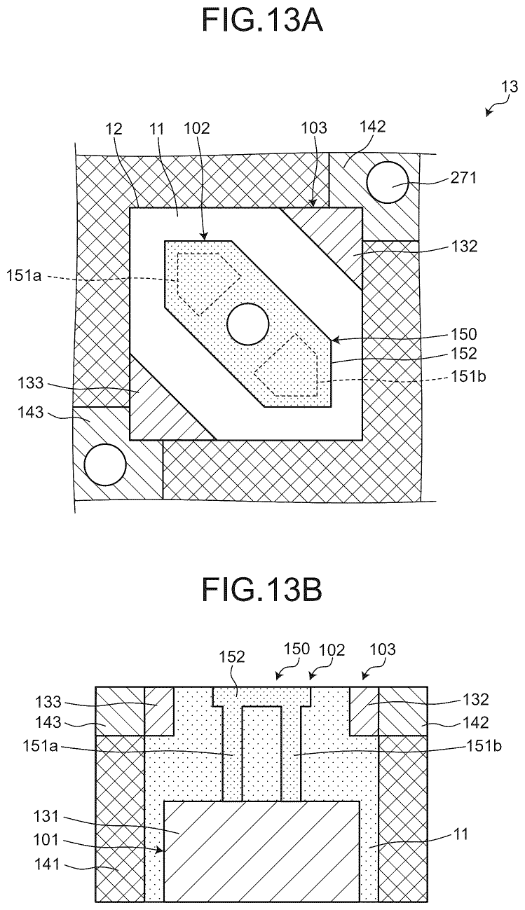

FIGS. 14A and 14B are diagrams illustrating another configuration example of the pixel according to the third embodiment of the present disclosure. FIG. 14A illustrates a configuration of a plane of the pixel 12, and FIG. 14B illustrates a configuration of a cross section of the pixel 12. FIGS. 14A and 14B illustrate an example in which the embedded insulating layer 157 is disposed around the flat plate electrode section 152. The embedded insulating layer 157 can be constituted by, for example, SiO₂. By disposing the embedded insulating layer 157, concentration of an electric field between the semiconductor region 132 constituting the charge holding section 103 and the flat plate electrode section 152 can be alleviated.

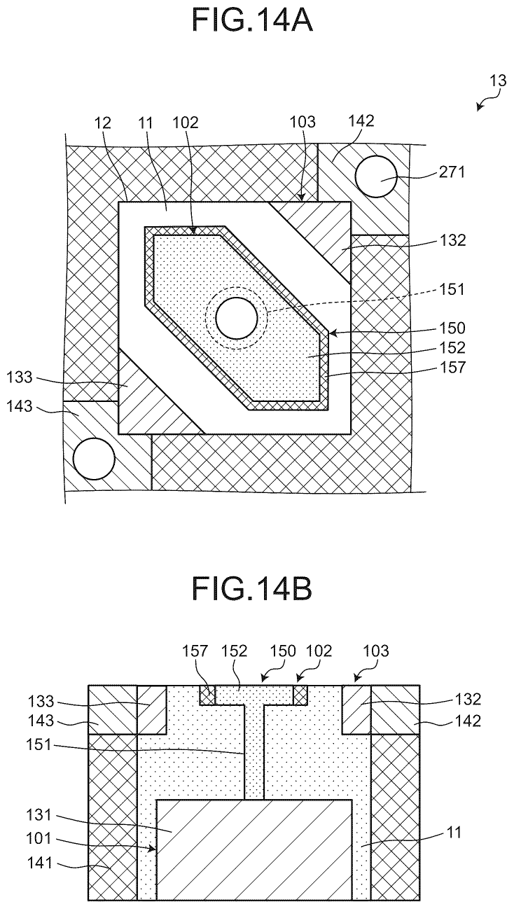

FIGS. 15A and 15B are diagrams illustrating another configuration example of the pixel according to the third embodiment of the present disclosure. FIG. 15A illustrates a configuration of a plane of the pixel 12, and FIG. 15B illustrates a configuration of a cross section of the pixel 12. FIGS. 15A and 15B illustrate an example in which the flat plate electrode section 152 is configured in a shape covering a part of the vertical electrode section 151.

Since the configuration of the photodetection apparatus 1 other than this is similar to the configuration of the photodetection apparatus 1 in the first embodiment of the present disclosure, the description thereof will be omitted.

### 4. Fourth Embodiment

In the photodetection apparatus 1 of the second embodiment described above, the photoelectric conversion section 101 is arranged in the vicinity of the back surface of the semiconductor substrate 11, and performs photoelectric conversion of incident light from the back surface side of the semiconductor substrate 11. On the other hand, a photodetection apparatus 1 according to a fourth embodiment of the present disclosure is different from that of the above-described second embodiment in that the photoelectric conversion section 101 is arranged in the vicinity of the front surface of the semiconductor substrate 11.

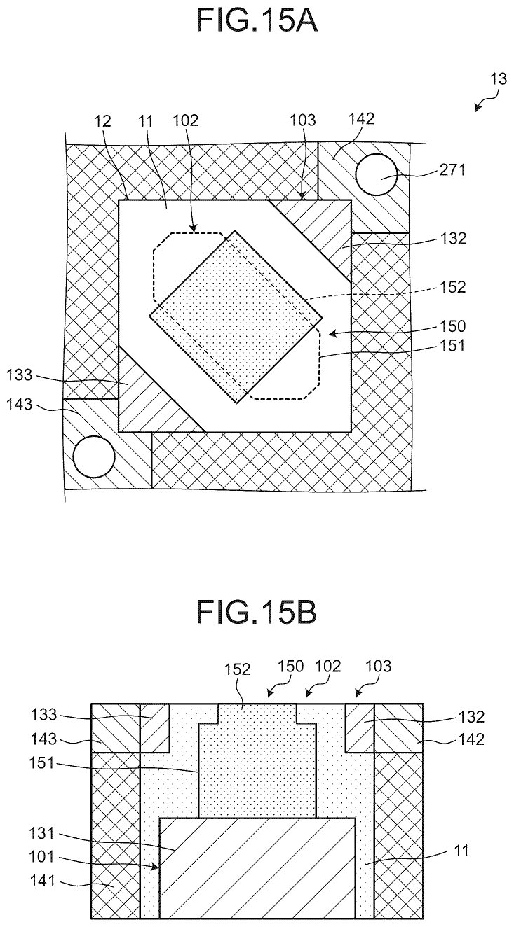

FIG. 16 is a diagram illustrating a configuration example of a pixel according to the fourth embodiment of the present disclosure. FIG. 16 is a cross-sectional view illustrating a configuration example of the pixel 12 similarly to FIG. 10. The pixel 12 in FIG. 16 is different from the pixel 12 in FIG. 10 in that the photoelectric conversion section 101 is arranged in the vicinity of the front surface of the semiconductor substrate 11 and performs photoelectric conversion of incident light incident on the front side of the semiconductor substrate 11. The photodetection apparatus 1 having such a configuration is referred to as a front-illuminated type.

The photoelectric conversion section 101 in FIG. 16 performs photoelectric conversion of incident light incident on the front side of the semiconductor substrate 11. As illustrated in FIG. 16, the semiconductor region 131 of the photoelectric conversion section 101 is disposed in the vicinity of the front surface of the semiconductor substrate 11. In addition, the semiconductor region 134 is disposed between the semiconductor region 131 and the front surface of the semiconductor substrate 11. The semiconductor region 134 is configured to have a relatively high impurity concentration and is a region where pinning of an interface state of the semiconductor region 131 is performed.

The charge transfer section 102 in FIG. 16 has a shape in which the vertical electrode section 151 and the flat plate electrode section 152 of the gate electrode 150 are embedded in the semiconductor substrate 11. In addition, the upper surface of the flat plate electrode section 152 is configured to have substantially the same height as the front surface of the semiconductor substrate 11.

Since the configuration of the photodetection apparatus 1 other than this is similar to the configuration of the photodetection apparatus 1 in the second embodiment of the present disclosure, the description thereof will be omitted.

As described above, the photodetection apparatus 1 according to the fourth embodiment of the present disclosure can easily connect the contact plug 163 to the gate electrode 150 in the pixel 12 including the semiconductor substrate 11.

### 5. Configuration of Electronic Device

The photodetection apparatus 1 as described above can be applied to various electronic devices such as an imaging system such as a digital still camera or a digital video camera, a mobile phone having an imaging function, or another device having an imaging function.

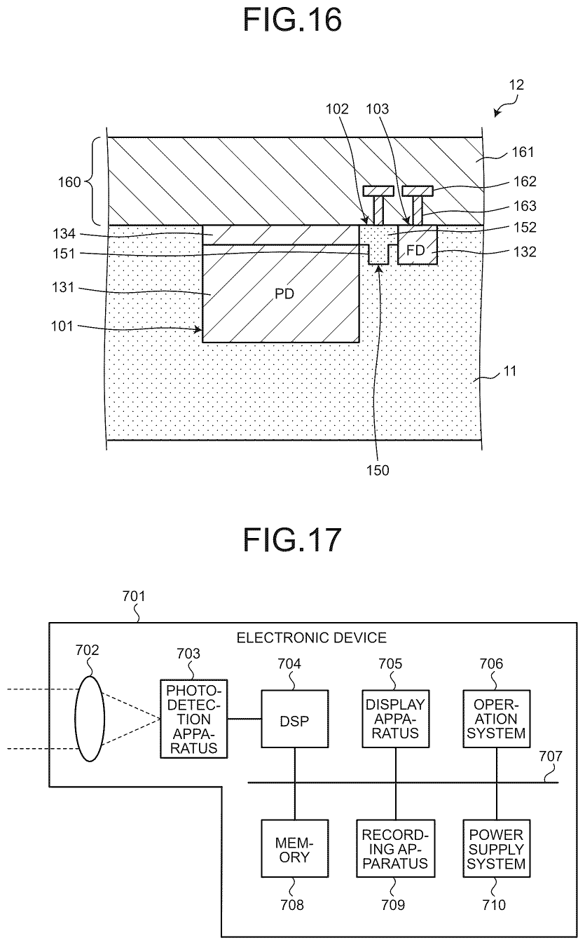

FIG. 17 is a block diagram illustrating a configuration example of an imaging apparatus mounted on an electronic device. As illustrated in FIG. 17, an electronic device 701 includes an optical system 702, a photodetection apparatus 703, and a digital signal processor (DSP) 704, and is configured by connecting a DSP 704, a display apparatus 705, an operation system 706, a memory 708, a recording apparatus 709, and a power supply system 710 via a bus 707, and is capable of capturing a still image and a moving image.

The optical system 702 includes one or a plurality of lenses, guides image light (incident light) from a subject to the photodetection apparatus 703, and forms an image on a light receiving surface (sensor section) of the photodetection apparatus 703.

As the photodetection apparatus 703, the photodetection apparatus 1 of any of the above-described configuration examples is applied. In the photodetection apparatus 703, electrons are accumulated for a certain period according to an image formed on the light receiving surface via the optical system 702. Then, a signal corresponding to the electrons accumulated in the photodetection apparatus 703 is input to the DSP 704.

The DSP 704 performs various types of signal processing on the signal from the photodetection apparatus 703 to acquire an image, and temporarily stores data of the image in the memory 708. The image data stored in the memory 708 is recorded in the recording apparatus 709 or supplied to the display apparatus 705 to display an image. In addition, the operation system 706 receives various operations by the user and supplies an operation signal to each block of the electronic device 701, and the power supply system 710 supplies power necessary for driving each block of the electronic device 701.

### 6. Example of Application to Mobile Body

The technology according to the present disclosure (the present technology) is applicable to various products. For example, the technology according to the present disclosure may be applied to devices mounted on any of mobile body such as automobiles, electric vehicles, hybrid electric vehicles, motorcycles, bicycles, personal mobility, airplanes, drones, ships, and robots.

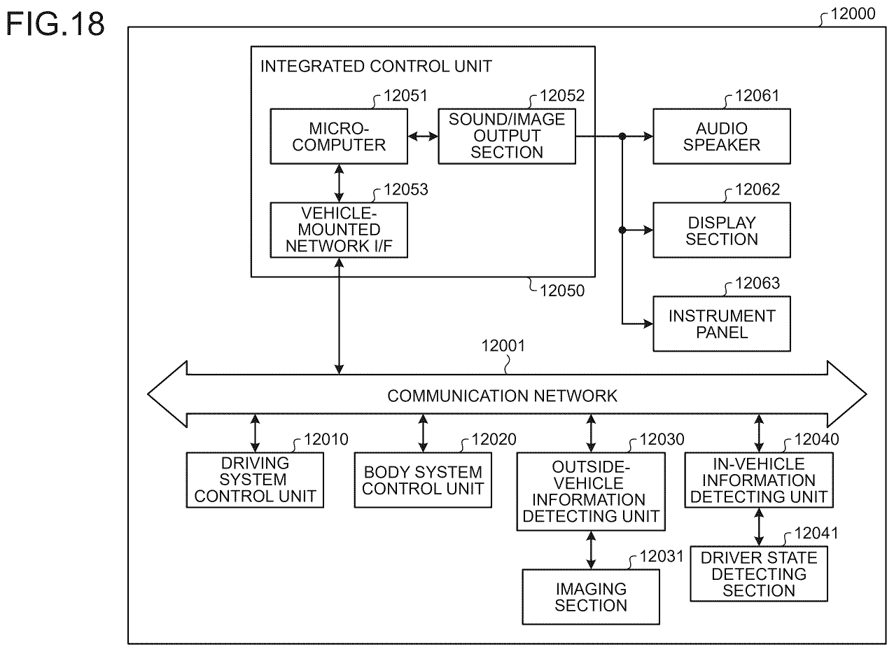

FIG. 18 is a block diagram depicting an example of schematic configuration of a vehicle control system as an example of a mobile body control system to which the technology according to an embodiment of the present disclosure can be applied.

A vehicle control system 12000 includes a plurality of electronic control units connected to each other via a communication network 12001. In the example depicted in FIG. 18, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 18, an audio speaker 12061, a display section 12062, and an instrument panel 12063 are illustrated as the output device. The display section 12062 may, for example, include at least one of an on-board display and a head-up display.

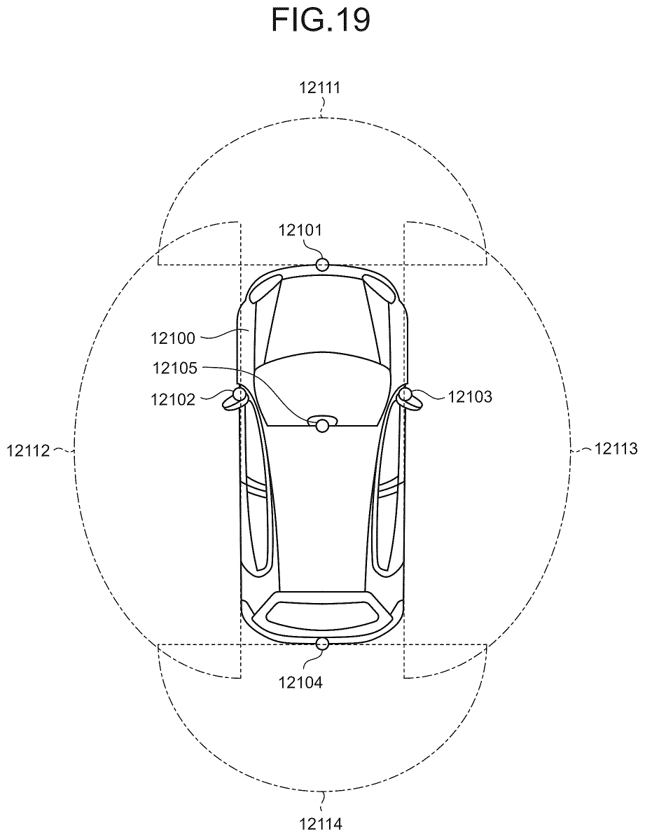

FIG. 19 is a diagram depicting an example of the installation position of the imaging section 12031.

In FIG. 19, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of a vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 19 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 among the configurations described above. Specifically, the photodetection apparatus 1 of FIG. 1 can be applied to the imaging section 12031.

### 7. Example of Application to Endoscopic Surgery System

The technology according to the present disclosure (the present technology) is applicable to various products. For example, the techniques according to the present disclosure may be applied to endoscopic surgery systems.

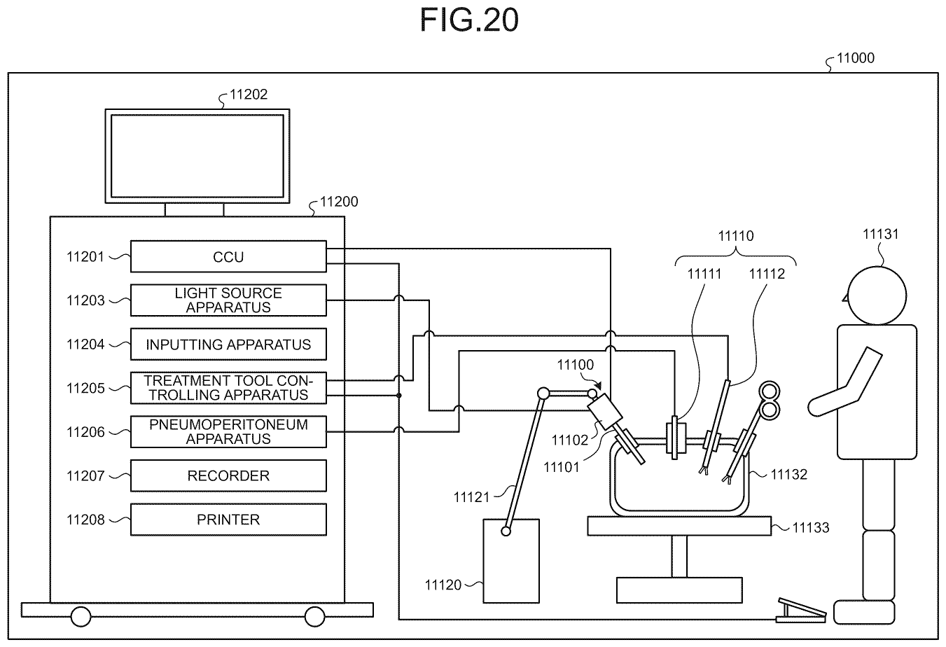

FIG. 20 is a view depicting an example of a schematic configuration of an endoscopic surgery system to which the technology according to an embodiment of the present disclosure (present technology) can be applied.

In FIG. 20, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy treatment tool 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body lumen of the patient 11132, and a camera head 11102 connected to a proximal end of the lens barrel 11101. In the example depicted, the endoscope 11100 is depicted which includes as a hard mirror having the lens barrel 11101 of the hard type. However, the endoscope 11100 may otherwise be included as a soft mirror having the lens barrel 11101 of the soft type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body lumen of the patient 11132 through the objective lens. It is to be noted that the endoscope 11100 may be a direct view mirror or may be a perspective view mirror or a side view mirror.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy treatment tool 11112 for cautery or incision of a tissue, sealing of a blood vessel or the like. A pneumoperitoneum apparatus 11206 feeds gas into a body lumen of the patient 11132 through the pneumoperitoneum tube 11111 to inflate the body lumen in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

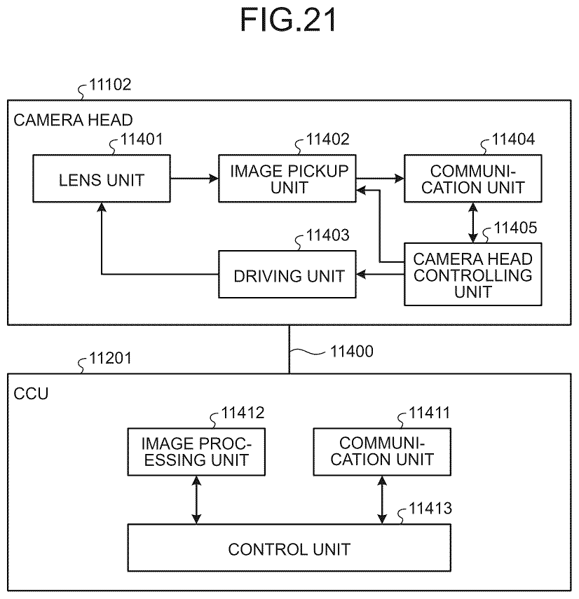

FIG. 21 is a block diagram depicting an example of a functional configuration of the camera head 11102 and the CCU 11201 depicted in FIG. 20.

The camera head 11102 includes a lens unit 11401, an image pickup unit 11402, a driving unit 11403, a communication unit 11404 and a camera head controlling unit 11405.

The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy treatment tool 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be applied to the endoscope 11100 and the image pickup unit 11402 of the camera head 11102 among the above-described configurations. Specifically, the photodetection apparatus 1 of FIG. 1 can be applied to the image pickup unit 11402.

Although the endoscopic surgery system has been described here as an example, the technique according to the present disclosure may be applied to, for example, a microscopic surgery system or the like.

Note that the effects described in the present specification are merely examples and are not limited, and other effects may be provided.

Note that the present technology can also have the following configurations.

(1) A semiconductor apparatus comprising:
a connection region disposed on a surface of a semiconductor substrate and being a region to which wiring is connected;
a photoelectric conversion section disposed in the semiconductor substrate and configured to perform photoelectric conversion of incident light;
a charge holding section that is disposed in the semiconductor substrate and holds a charge generated by the photoelectric conversion; and
a charge transfer section configured by a MOS transistor including a gate electrode including a vertical electrode section disposed in the semiconductor substrate and a flat plate electrode section embedded in a surface of the semiconductor substrate, the flat plate electrode section having a size in a plane direction of the semiconductor substrate different from that of the vertical electrode section, the flat plate electrode section having wiring connected to an upper surface of the flat plate electrode section, the charge transfer section being configured to transfer a charge of the photoelectric conversion section to the charge holding section.

(2) The semiconductor apparatus according to the above (1), wherein the upper surface of the flat plate electrode section is configured to have substantially a same height as an upper surface of the connection region.

(3) The semiconductor apparatus according to the above (1), wherein the upper surface of the flat plate electrode section is configured to have substantially a same height as a surface of the semiconductor substrate.

(4) The semiconductor apparatus according to any one of the above (1) to (3), wherein the connection region includes an embedded electrode embedded in a front surface side of the semiconductor substrate.

(5) The semiconductor apparatus according to the above (4), wherein an upper surface of the embedded electrode is configured to have a height between the upper surface and a lower surface of the flat plate electrode section.

(6) The semiconductor apparatus according to the above (4), wherein the embedded electrode is an electrode connected to the charge holding section.

(7) The semiconductor apparatus according to the above (4), wherein the embedded electrode is an electrode that transmits a reference potential to the semiconductor substrate.

(8) The semiconductor apparatus according to any one of the above (1) to (3), wherein the connection region is a semiconductor region constituting the charge holding section.

(9) The semiconductor apparatus according to any one of the above (1) to (8), further comprising:
first columnar wiring connected to the flat plate electrode section; and
second columnar wiring connected to the connection region.

(10) The semiconductor apparatus according to the above (9), wherein the flat plate electrode section is configured to have a size corresponding to the first columnar wiring.

(11) The semiconductor apparatus according to the above (10), wherein the flat plate electrode section is configured in a shape of an end portion extended outward by 30% or more of a diameter of the first columnar wiring with respect to an end portion of the vertical electrode section in plan view.

(12) The semiconductor apparatus according to the above (9), further comprising
a second semiconductor substrate laminated on the semiconductor substrate, wherein
the first columnar wiring is connected to wiring of a wiring region disposed on the second semiconductor substrate, and
the second columnar wiring is connected to wiring of a wiring region disposed on the second semiconductor substrate.

(13) The semiconductor apparatus according to any one of the above (1) to (12), wherein the charge transfer section includes the gate electrode having a plurality of the vertical electrode section.

(14) The semiconductor apparatus according to any one of the above (1) to (13), wherein the charge transfer section includes a plurality of the gate electrode.

(15) The semiconductor apparatus according to any one of the above (1) to (14), further comprising an embedded insulating layer that is an insulating layer embedded in the semiconductor substrate around the flat plate electrode section.

(16) The semiconductor apparatus according to any one of the above (1) to (15), wherein the vertical electrode section has a columnar shape with a bottom portion in contact with the photoelectric conversion section.

(17) The semiconductor apparatus according to any one of the above (1) to (16), further comprising a signal generation section that generates a signal based on the charge held in the charge holding section.

(18) The semiconductor apparatus according to any one of the above (1) to (17), wherein the semiconductor apparatus is configured as a photodetection apparatus.

(19) An electronic device comprising:
a connection region disposed on a surface of a semiconductor substrate and being a region to which wiring is connected;
a photoelectric conversion section disposed in the semiconductor substrate and configured to perform photoelectric conversion of incident light;
a charge holding section that is disposed in the semiconductor substrate and holds a charge generated by the photoelectric conversion;
a charge transfer section configured by a MOS transistor including a gate electrode including a vertical electrode section disposed in the semiconductor substrate and a flat plate electrode section embedded in a surface of the semiconductor substrate, the flat plate electrode section having a size in a plane direction of the semiconductor substrate different from that of the vertical electrode section, the flat plate electrode section having wiring connected to an upper surface of the flat plate electrode section, the charge transfer section being configured to transfer a charge of the photoelectric conversion section to the charge holding section; and
a processing circuit that processes a signal based on the charge held in the charge holding section.

### REFERENCE SIGNS LIST

1, 703 PHOTODETECTION APPARATUS
11, 21, 31 SEMICONDUCTOR SUBSTRATE
12 PIXEL
22 READOUT CIRCUIT
34 COLUMN SIGNAL PROCESSING CIRCUIT
101 PHOTOELECTRIC CONVERSION SECTION
102 CHARGE TRANSFER SECTION
103 CHARGE HOLDING SECTION
142, 143 EMBEDDED ELECTRODE
150, 150a, 150b GATE ELECTRODE
151, 151a, 151b VERTICAL ELECTRODE SECTION
152 FLAT PLATE ELECTRODE SECTION
157 EMBEDDED INSULATING LAYER
163 CONTACT PLUG
271 THROUGH WIRING
701 ELECTRONIC DEVICE
11402, 12031, 12101 to 12105 IMAGE PICKUP UNIT, IMAGING SECTION

What is claimed is:

1. A semiconductor apparatus, comprising:
a connection region disposed on a surface of a semiconductor substrate and being a region to which wiring is connected;
a photoelectric conversion section disposed in the semiconductor substrate and configured to perform photoelectric conversion of incident light;
a charge holding section that is disposed in the semiconductor substrate and holds a charge generated by the photoelectric conversion; and
a charge transfer section configured by a MOS transistor including a gate electrode including a vertical electrode section disposed in the semiconductor substrate and a flat plate electrode section embedded in a surface of the semiconductor substrate, the flat plate electrode section having a size in a plane direction of the semiconductor substrate different from that of the vertical electrode section, the flat plate electrode section having wiring connected to an upper surface of the flat plate electrode section, the charge transfer section being configured to transfer a charge of the photoelectric conversion section to the charge holding section.

2. The semiconductor apparatus according to claim 1, wherein the upper surface of the flat plate electrode section is configured to have substantially a same height as an upper surface of the connection region.

3. The semiconductor apparatus according to claim 1, wherein the upper surface of the flat plate electrode section is configured to have substantially a same height as a surface of the semiconductor substrate.

4. The semiconductor apparatus according to claim 1, wherein the connection region includes an embedded electrode embedded in a front surface side of the semiconductor substrate.

5. The semiconductor apparatus according to claim 4, wherein an upper surface of the embedded electrode is configured to have a height between the upper surface and a lower surface of the flat plate electrode section.

6. The semiconductor apparatus according to claim 4, wherein the embedded electrode is an electrode connected to the charge holding section.

7. The semiconductor apparatus according to claim 4, wherein the embedded electrode is an electrode that transmits a reference potential to the semiconductor substrate.

8. The semiconductor apparatus according to claim 1, wherein the connection region is a semiconductor region constituting the charge holding section.

9. The semiconductor apparatus according to claim 1, further comprising:
first columnar wiring connected to the flat plate electrode section; and
second columnar wiring connected to the connection region.

10. The semiconductor apparatus according to claim 9, wherein the flat plate electrode section is configured to have a size corresponding to the first columnar wiring.

11. The semiconductor apparatus according to claim 10, wherein the flat plate electrode section is configured in a shape of an end portion extended outward by 30% or more of a diameter of the first columnar wiring with respect to an end portion of the vertical electrode section in plan view.

12. The semiconductor apparatus according to claim 9, further comprising
a second semiconductor substrate laminated on the semiconductor substrate, wherein
the first columnar wiring is connected to wiring of a wiring region disposed on the second semiconductor substrate, and
the second columnar wiring is connected to wiring of a wiring region disposed on the second semiconductor substrate.

13. The semiconductor apparatus according to claim 1, wherein the charge transfer section includes the gate electrode having a plurality of the vertical electrode section.

14. The semiconductor apparatus according to claim 1, wherein the charge transfer section includes a plurality of the gate electrode.

15. The semiconductor apparatus according to claim 1, further comprising an embedded insulating layer that is an insulating layer embedded in the semiconductor substrate around the flat plate electrode section.

16. The semiconductor apparatus according to claim 1, wherein the vertical electrode section has a columnar shape with a bottom portion in contact with the photoelectric conversion section.

17. The semiconductor apparatus according to claim 1, further comprising a signal generation section that generates a signal based on the charge held in the charge holding section.

18. The semiconductor apparatus according to claim 1, wherein the semiconductor apparatus is configured as a photodetection apparatus.

19. An electronic device, comprising:
a connection region disposed on a surface of a semiconductor substrate and being a region to which wiring is connected;
a photoelectric conversion section disposed in the semiconductor substrate and configured to perform photoelectric conversion of incident light;
a charge holding section that is disposed in the semiconductor substrate and holds a charge generated by the photoelectric conversion;
a charge transfer section configured by a MOS transistor including a gate electrode including a vertical electrode section disposed in the semiconductor substrate and a flat plate electrode section embedded in a surface of the semiconductor substrate, the flat plate electrode section having a size in a plane direction of the semiconductor substrate different from that of the vertical electrode section, the flat plate electrode section having wiring connected to an upper surface of the flat plate electrode section, the charge transfer section being configured to transfer a charge of the photoelectric conversion section to the charge holding section; and
a processing circuit that processes a signal based on the charge held in the charge holding section.
